(19) United States
(12) Patent Application Publication
(10) Pub. No.: US 2006/0146505 A1
(43) Pub. Date: Jul. 6, 2006

(54) Plasma display device

(76) Inventors: Sok-San Kim, Suwon-si (KR); Ki-Jung Kim, Suwon-si (KR); Tae-Kyoung Kang, Suwon-si (KR); Joong-Ha Ahn, Suwon-si (KR); Myoung-Kon Kim, Suwon-si (KR)

Correspondence Address: LEE & MORSE, P.C., 1101 WILSON BOULEVARD, SUITE 2000, ARLINGTON, VA, 22209, US

(21) Appl. No.: 11/325,328

(22) Filed: Jan. 5, 2006

(30) Foreign Application Priority Data
Jan. 5, 2005 (KR) 10-2005-0000794

(51) Int. Cl. H05K 5/00

(52) U.S. Cl. 361/752; 361/753; 361/759

(57) ABSTRACT

A plasma display device including a cover plate, which can ground a directly attached filter, including a plasma display panel including a directly attached filter, a circuit board driving the plasma display panel, a chassis having the plasma display panel and the circuit board mounted thereon, a signal transmitting member electrically connected to the circuit board and the plasma display panel, the signal transmitting member including an integrated circuit chip, and a cover plate mounted to the chassis to face the integrated circuit chip, the cover plate including a contact portion contacting the directly attached filter.

### BACKGROUND OF THE INVENTION

1. Field of the Invention

The present invention relates to a plasma display device. More particularly, the present invention relates to a plasma display device including a cover plate that can ground a directly attached filter.

2. Description of the Related Art

Plasma display devices are recently drawing attention as substitute devices for conventional cathode ray tube (CRT) display devices. Plasma display devices generally incorporate a discharge gas injected and sealed between two substrates on which phosphor materials and a plurality of electrodes are formed. Plasma display devices may display a desired image by applying a voltage between the substrates to generate a plasma discharge in the discharge gas. The plasma discharge produces ultraviolet light, which excites the phosphor materials to emit the visible light that forms the desired image.

To improve the quality of plasma display devices, a filter is typically employed. For example, a filter may shield harmful electromagnetic radiation generated by the plasma display devices, may block neon light or near-infrared light that may cause malfunctions of wireless devices such as telephones, remote controls, etc., and may prevent the reflection of external light from a front surface of a plasma display panel.

In general, the filter is made of glass to which multi-layered films are attached, and is mounted in front of the plasma display panel. The filter may be directly attached to the plasma display panel. The directly attached filter is commonly made of a thin synthetic resin film instead of glass, making it possible to realize a light and thin plasma display device. Accordingly, the use of directly attached filters has been increasing.

To shield electromagnetic radiation or the like, the directly attached filter needs to be grounded. Since an additional grounding member is required to ground the directly attached filter to a case or a chassis, manufacturing costs and the number of components increase.

### SUMMARY OF THE INVENTION

The present invention is therefore directed to a plasma display device including a cover plate that can ground a directly attached filter, which substantially overcomes one or more of the problems due to the limitations and disadvantages of the related art.

It is therefore a feature of an embodiment of the present invention to provide a cover plate that grounds a directly attached filter.

It is therefore another feature of an embodiment of the present invention to provide a cover plate that grounds a front portion of a directly attached filter along its length.

It is therefore a further feature of an embodiment of the present invention to provide a cover plate that grounds a directly attached filter and supports and contains elements of the plasma display device.

At least one of the above and other features and advantages of the present invention may be realized by providing a plasma display device including a plasma display panel including a directly attached filter, a circuit board driving the plasma display panel, a chassis having the plasma display panel and the circuit board mounted thereon, a signal transmitting member electrically connected to the circuit board and the plasma display panel, the signal transmitting member including an integrated circuit chip, and a cover plate mounted to the chassis to face the integrated circuit chip, the cover plate including a contact portion contacting the directly attached filter.

The contact portion may be made of the same material as the cover plate. The cover plate and the contact portion may be formed from a single piece of the material. The contact portion may have at least one groove formed therein. The plasma display device may further include a case housing the plasma display panel, the circuit board, the chassis, the signal transmitting member, and the cover plate. The plasma display device may further include a mounting bolt attaching the cover plate to the chassis, the mounting bolt penetrating the cover plate opposite the contact portion. The directly attached filter may be grounded to the chassis by the cover plate.

At least one of the above and other features and advantages of the present invention may also be realized by providing a plasma display device including a chassis having a circuit board mounted to a rear surface, a plasma display panel mounted to a front surface of the chassis, the plasma display panel having a filter directly attached to a front surface thereof, wherein a rear surface of the plasma display panel faces a front surface of the chassis, signaling means for providing signals between the circuit board and the plasma display panel, the signaling means coupled between the circuit board and the plasma display panel, and grounding means for electrically grounding the chassis to the filter, the grounding means disposed adjacent to the rear surface of the chassis and adjacent to a front surface of the filter.

The filter may include a conductive layer substantially coextensive with an entire area of the filter, the conductive layer having an exposed portion on the front surface of the filter. The grounding means may electrically couple the chassis to the exposed portion of the conductive layer. The grounding means may include a clamping member, the clamping member having a substantially U-shaped cross section, such that the clamping member has first and second legs facing each other. The first leg of the clamping member may be disposed adjacent to the rear surface of the chassis and the second leg of the clamping member may be disposed adjacent to the front surface of the filter. The signaling means may include an integrated circuit mounted to a heat dissipater, the heat dissipater disposed between the first leg of the clamping member and the rear surface of the chassis. The signaling means may include an integrated circuit. The signaling means may be a tape carrier package.

At least one of the above and other features and advantages of the present invention may further be realized by providing a plasma display device including a plasma display panel, a chassis and an electrical ground coupling the plasma display panel to the chassis, wherein the electrical ground is provided by a U-shaped member disposed in front of a front surface of the plasma display panel and behind the chassis. The plasma display device may further include a filter attached to the front surface of the plasma display panel, wherein the filter includes a transparent conductive layer substantially coextensive with an entire area of the filter, the conductive layer having an exposed portion on the front surface of the filter, and the exposed portion is attached and electrically grounded to the U-shaped member.

The exposed portion may be directly attached to the U-shaped member. The front surface of the plasma display panel may have a height and a width, the exposed portion of the conductive layer may extend along a peripheral region of the front surface along the width, and the exposed portion may be electrically grounded to the U-shaped member at a plurality of points. The exposed portion may be in continuous contact with the U-shaped member along the width.

### BRIEF DESCRIPTION OF THE DRAWINGS

The above and other features and advantages of the present invention will become more apparent to those of ordinary skill in the art by describing in detail exemplary embodiments thereof with reference to the attached drawings in which:

FIG. 1 illustrates an exploded perspective view of a plasma display device according to an embodiment of the present invention;

FIG. 2 illustrates an enlarged sectional view of a grounding structure for a directly attached filter of the plasma display device of FIG. 1; and

FIG. 3 illustrates a perspective view of a cover plate according to an embodiment of the present invention.

### DETAILED DESCRIPTION OF THE INVENTION

Korean Patent Application No. 10-2005-000794, filed on Jan. 5, 2002, in the Korean Intellectual Property Office, and entitled: “Plasma Display Device,” is incorporated by reference herein in its entirety.

The present invention will now be described more fully hereinafter with reference to the accompanying drawings, in which exemplary embodiments of the invention are shown. The invention may, however, be embodied in different forms and should not be construed as limited to the embodiments set forth herein. Rather, these embodiments are provided so that this disclosure will be thorough and complete, and will fully convey the scope of the invention to those skilled in the art. In the figures, the dimensions of layers and regions are exaggerated for clarity of illustration. It will also be understood that when a layer is referred to as being “on” another layer or substrate, it can be directly on the other layer or substrate, or intervening layers may also be present. Further, it will be understood that when a layer is referred to as being “under” another layer, it can be directly under, and one or more intervening layers may also be present. In addition, it will also be understood that when a layer is referred to as being “between” two layers, it can be the only layer between the two layers, or one or more intervening layers may also be present. Like reference numerals refer to like elements throughout.

According to the present invention, a plasma display device may ground a directly attached filter using a cover plate, such that an additional grounding member is not required, thereby reducing manufacturing costs and the number of components.

A contact portion of the cover plate contacting a grounding part of the directly attached filter may have a large area. Thus, the grounding performance can be improved and electromagnetic radiation and near-infrared light generated by the plasma display device can be shielded efficiently.

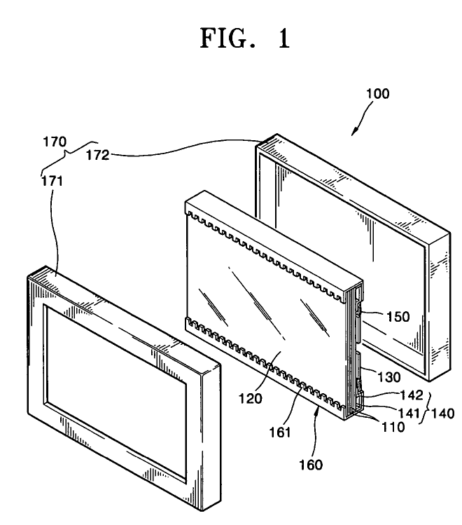

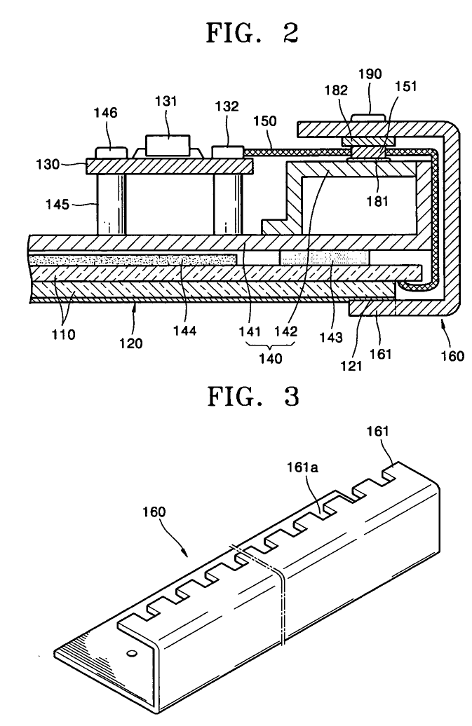

FIG. 1 illustrates an exploded perspective view of a plasma display device according to an embodiment of the present invention, FIG. 2 illustrates an enlarged sectional view of a grounding structure for a directly attached filter of the plasma display device of FIG. 1, and FIG. 3 illustrates a perspective view of a cover plate according to an embodiment of the present invention.

Referring to FIGS. 1 and 2, a plasma display device 100 may include a plasma display panel 110 for displaying an image, a directly attached filter 120, a circuit board 130, a chassis 140, signal transmitting member 150, a cover plate 160, and a case 170.

The plasma display panel 110 may be mounted in front of the chassis 140 and may be coupled to the chassis 140 using, e.g., an adhering member 143 applied to a rear surface of the plasma display panel 110. The adhering member 143 may be, e.g., double-faced tape.

A panel heat dissipating sheet 144 having high heat conductivity may be interposed between the plasma display panel 110 and the chassis 140 to efficiently disperse and dissipate heat generated during the operation of the plasma display panel 110.

The directly attached filter 120 may be attached to a front surface of the plasma display panel 110 and may include a conductive layer and an external light reflection preventing layer formed on a base film thereof.

The conductive layer may be a thin transparent layer and may be formed in, e.g., a mesh pattern. The conductive layer may be made of a conductive material such as Indium Tin Oxide (ITO), Ag, Au, Cu, Al, etc. The external light reflection preventing layer may be made of a material with high darkness. The base film used as a base of the filter 120 may be made of, e.g., polyethersulphone (PES), polyacrylate (PAR), polyetherimide (PEI), polyethyelene naphthalate (PEN), polyethyelene terephthalate (PET), polyphenylene sulfide (PPS), polyallylate, polyimide, etc.

Although the directly attached filter 120 is described herein as including the conductive layer and the external light reflection preventing layer formed on the base film, the present invention is not limited thereto. In other implementations, a hard coating material for preventing scratching, may be coated on the external light reflection preventing layer, a selective absorption layer, for absorbing light with a predetermined wavelength, may be formed between the conductive layer and the external light reflection preventing layer, etc. Additionally, although the directly attached filter 120 is described herein as including one base film, the present invention is not limited thereto. In other implementations, the directly attached filter may be formed by stacking a plurality of films.

A grounding part 121 connected to the conductive layer may be formed along an edge of the directly attached filter 120. The grounding part 121 may be electrically connected to the cover plate 160 to perform grounding. The grounding part 121 may be, e.g., a region of transparent conductive material exposed along a periphery of the directly attached filter 120. The grounding part 121 may be electrically connected to the cover plate 160 along a length of the cover plate 160 and may have a plurality of grounding connections thereto, which may be multiple individual grounding points, an essentially continuous grounding connection along the length, etc.

A circuit element 131 and a connector 132 may be disposed on the circuit board 130 to drive the plasma display panel 110. The circuit board 130 may be mounted over the chassis 140 using a boss 145 and an installation bolt 146. The chassis 140 may be made of Al, Fe, etc., and may include a chassis base 141 and a reinforcing member 142. The reinforcing member 142 may be attached to an end portion of the chassis 140 and may have a height similar to that of the circuit board 130.

The signal transmitting member 150 may serve to transmit an address signal and may be installed over the reinforcing member 142. The signal transmitting member 150 may be connected at one end to the connector 132 mounted on the circuit board 130, and may be connected at the other end to an electrode terminal part of the plasma display panel 110. The signal transmitting member 150 may be a tape carrier package (TCP) including an integrated circuit chip 151. The integrated circuit chip 151 may be installed on the reinforcing member 142, and may control an electrical signal passing through the signal transmitting member 150.

Although the chassis 140 may include the reinforcing member 142 to reinforce the rigidity of the chassis 140, and the integrated circuit chip 151 may be mounted on the reinforcing member 142, the present invention is not limited thereto. In some implementations, rigidity of the chassis 140 may be improved by bending an edge portion of the chassis 140, instead of the reinforcing member 142, to form a bent portion. The integrated circuit chip 151 may be installed on the bent portion of the chassis 140.

Thermal grease 181 may be put between the integrated circuit chip 151 and the reinforcing member 142. A chip heat dissipating sheet 182 may be interposed between the integrated circuit chip 151 and the cover plate 160. The chip heat dissipating sheet 182 may be secured between the cover plate 160 and the reinforcing member 142 by, e.g., a mounting bolt 190. The chip heat dissipating sheet 182 may dissipate heat, generated by the integrated circuit chip 151, to the cover plate 160. Although the thermal grease 181 is described herein as being used between the integrated circuit chip 151 and the reinforcing member 142, the present invention is not limited thereto. In some implementations, a heat dissipating sheet may be installed instead of the thermal grease 181, or the integrated circuit chip 151 may directly contact the reinforcing member 142 without the thermal grease 181. Further, although the chip heat dissipating sheet 182 is described herein as being installed on the integrated circuit chip 151, the present invention is not limited thereto. In some implementations, thermal grease may be used instead of the chip heat dissipating sheet 182, or the integrated circuit chip 151 may directly contact the cover plate 160 without the chip heat dissipating sheet 182.

The cover plate 160 may be mounted on the reinforcing member 142 using, e.g., the mounting bolt 190. The cover plate 160 may protect the signal transmitting member 150 and the integrated circuit chip 151, and may dissipate heat generated by the integrated circuit chip 151.

In detail, as illustrated in FIGS. 2 and 3, the cover plate 160 may be formed with one or more angles therein, such that the cover plate 160 is folded lengthwise to have, e.g., a U-shaped cross-section. The U-shaped cross-section may include two legs, which may have different lengths if required to suit the particular implementation. The cover plate 160 may be formed by, e.g., stamping or forming a single piece of material.

The cover plate 160 may have a contact portion 161, which may contact the grounding part 121 of the directly attached filter 120 to perform grounding. The contact portion 161 may have grooves 161a, such that the contact portion 161 is shaped like a strip of fingers. The contact portion 161 and the cover plate 160 may be formed of the same material and may be formed from a single piece of the material, e.g., by stamping, bending, etc. Since it is easy to adjust the elastic force of the finger strip-shaped contact portion 161, the contact portion 161 may easily contact the grounding part 121 and may also be installed more easily. The contact portion 161 may be in more-or-less continuous contact with the grounding part 121, which may enable better grounding performance. Although the contact portion 161 of the cover plate 160 is described herein as including the grooves 161a, the present invention is not limited thereto. In some implementations, the contact portion 161 of the cover plate 160 may have a simple plate shape, i.e., it may be substantially planar.

The cover plate 160 may be made of the same material as the contact portion 161, although the present invention is not limited thereto. If both the body of the cover plate 160 and the contact portion 161 are made of conductive materials, the conductive materials of the body of the cover plate 160 and the contact portion 161 may be different from each other. The cover plate 160 may be integrally formed with the contact portion 161, although the present invention is not limited thereto. In some implementations, after the cover plate 160 and the contact portion 161 are separately manufactured, the contact portion may be attached to the body of the cover plate using, e.g., a conductive adhesive.

The contact portion 161 of the cover plate 160 may be as long as the cover plate 160. Accordingly, the cover plate 160 may contact the grounding part 121 of the directly attached filter 120 to perform grounding over a large area. Thus, large amounts of energy, e.g., electromagnetic radiation and near-infrared light, may be quickly absorbed through the large contact area of the contact portion 161. Therefore, the efficiency of shielding electromagnetic radiation, etc., may be improved.

The case 170 may include a front case 171 having a window and disposed in front of the chassis 140. The case 170 may also include a rear case 172 disposed behind the chassis 140. The case 170 may house the plasma display panel 110, the circuit board 130, the chassis 140, the signal transmitting member 150, and the cover plate 160.

The grounding structure for the directly attached filter 120 may be installed according to the following description. The integrated circuit chip 151 may be mounted on a predetermined portion of the reinforcing member 142. An external force may be applied to the cover plate 160 to elastically spread out the cover plate 160. The cover plate 160 may be placed onto an edge of an assembly including the plasma display panel 110 and the chassis 140, where it may remain due to the elastic force. The contact portion 161 of the cover plate 160 may contact the grounding part 121 of the directly attached filter 120. A conductive adhesive may be coated on the contact portion 161 to ensure that the contact portion 161 is electrically well-connected to the grounding part 121. The part of the cover plate 160 to be mounted over the reinforcing member 142 may be positioned to accommodate the mounting bolt 190, and may be affixed using the mounting bolt 190. The mounting bolt 190 may ground the cover plate 160 to the reinforcing member 142, and thus to the chassis 140.

The plasma display device 100, including the directly attached filter 120 attached to the plasma display panel 110, may be operated according to the following description. When the plasma display device 100 is operated by a user, voltage may be applied from the circuit board 130 to the plasma display panel 110, causing an address discharge and a sustain discharge to occur such that an energy level of a discharge gas is excited, and then decreases by emitting ultraviolet light. The ultraviolet light excites a phosphor material of a phosphor layer coated in a discharge cell, and the energy level of the excited phosphor material decreases to emit visible light. Due to the emitted visible light, an image can be displayed.

Since the grounding part 121 of the directly attached filter 120 may be electrically connected to the cover plate 160, and the cover plate 160 may be electrically connected to the chassis 140 using, e.g., the mounting bolt 190, the directly attached filter 120 may be grounded. Accordingly, the directly attached filter 120 may absorb and shield electromagnetic radiation, near-infrared light, etc., discharged from the plasma display device 100. Since the plasma display device 100 may ground the directly attached filter 120 using the cover plate 160 as described above, the grounding process can be simplified and manufacturing costs can be reduced.

Exemplary embodiments of the present invention have been disclosed herein, and although specific terms are employed, they are used and are to be interpreted in a generic and descriptive sense only and not for purpose of limitation. Accordingly, it will be understood by those of ordinary skill in the art that various changes in form and details may be made without departing from the spirit and scope of the present invention as set forth in the following claims.

What is claimed is:

1. A plasma display device, comprising:
a plasma display panel including a directly attached filter;
a circuit board driving the plasma display panel;
a chassis having the plasma display panel and the circuit board mounted thereon;
a signal transmitting member electrically connected to the circuit board and the plasma display panel, the signal transmitting member including an integrated circuit chip; and
a cover plate mounted to the chassis to face the integrated circuit chip, the cover plate including a contact portion contacting the directly attached filter.

2. The plasma display device as claimed in claim 1, wherein the contact portion is made of the same material as the cover plate.

3. The plasma display device as claimed in claim 2, wherein the cover plate and the contact portion are formed from a single piece of the material.

4. The plasma display device as claimed in claim 1, wherein the contact portion has at least one groove formed therein.

5. The plasma display device as claimed in claim 1, further comprising a case housing the plasma display panel, the circuit board, the chassis, the signal transmitting member, and the cover plate.

6. The plasma display device as claimed in claim 1, further comprising a mounting bolt attaching the cover plate to the chassis, the mounting bolt penetrating the cover plate opposite the contact portion.

7. The plasma display device as claimed in claim 6, wherein the directly attached filter is grounded to the chassis by the cover plate.

8. A plasma display device, comprising:
a chassis having a circuit board mounted to a rear surface;
a plasma display panel mounted to a front surface of the chassis, the plasma display panel having a filter directly attached to a front surface thereof, wherein a rear surface of the plasma display panel faces a front surface of the chassis;
signaling means for providing signals between the circuit board and the plasma display panel, the signaling means coupled between the circuit board and the plasma display panel; and
grounding means for electrically grounding the chassis to the filter, the grounding means disposed adjacent to the rear surface of the chassis and adjacent to a front surface of the filter.

9. The plasma display panel of claim 8, wherein the filter includes a conductive layer substantially coextensive with an entire area of the filter, the conductive layer having an exposed portion on the front surface of the filter.

10. The plasma display panel of claim 9, wherein the grounding means electrically couples the chassis to the exposed portion of the conductive layer.

11. The plasma display panel of claim 8, wherein the grounding means includes a clamping member, the clamping member having a substantially U-shaped cross section, such that the clamping member has first and second legs facing each other.

12. The plasma display panel of claim 11, wherein the first leg of the clamping member is disposed adjacent to the rear surface of the chassis and the second leg of the clamping member is disposed adjacent to the front surface of the filter.

13. The plasma display panel of claim 11, wherein the signaling means includes an integrated circuit mounted to a heat dissipater, the heat dissipater disposed between the first leg of the clamping member and the rear surface of the chassis.

14. The plasma display device of claim 8, wherein the signaling means includes an integrated circuit.

15. The plasma display device of claim 14, wherein the signaling means is a tape carrier package.

16. A plasma display device, comprising:
a plasma display panel;
a chassis; and
an electrical ground coupling the plasma display panel to the chassis, wherein the electrical ground is provided by a U-shaped member disposed in front of a front surface of the plasma display panel and behind the chassis.

17. The plasma display device as claimed in claim 16, further comprising a filter attached to the front surface of the plasma display panel, wherein:
the filter includes a transparent conductive layer substantially coextensive with an entire area of the filter, the conductive layer having an exposed portion on the front surface of the filter, and
the exposed portion is attached and electrically grounded to the U-shaped member.

18. The plasma display device as claimed in claim 17, wherein the exposed portion is directly attached to the U-shaped member.

19. The plasma display device as claimed in claim 17, wherein the front surface of the plasma display panel has a height and a width, the exposed portion of the conductive layer extends along a peripheral region of the front surface along the width, and the exposed portion is electrically grounded to the U-shaped member at a plurality of points.

20. The plasma display device as claimed in claim 19, wherein the exposed portion is in continuous contact with the U-shaped member along the width.
